(19) United States
(12) Patent Application Publication
(10) Pub. No.: US 2025/0283934 A1
(43) Pub. Date: Sep. 11, 2025

(54) QUASISTATIC C-V METHOD WITH FIXED FORCE DC CURRENT AND LEAKAGE CORRECTION

(71) Applicant: Keithley Instruments, LLC, Solon, OH (US)

(72) Inventors: Mary Anne Tupta, Twinsburg, OH (US); Alexander N. Pronin, Twinsburg, OH (US)

(73) Assignee: Keithley Instruments, LLC, Solon, OH (US)

(21) Appl. No.: 19/064,950

(22) Filed: Feb. 27, 2025

Related U.S. Application Data
(60) Provisional application No. 63/562,841, filed on Mar. 8, 2024.
(60) Provisional application No. 63/700,105, filed on Sep. 27, 2024.

(51) Int. Cl. G01R 31/26

(52) U.S. Cl. CPC G01R 31/2621

(57) ABSTRACT

A test and measurement instrument is described, having: a current source configured to output a constant current to a device under test (DUT); a voltage sensor configured to sense a voltage to the DUT, where the voltage sensor is configured to: measure a first set of voltages over time while the current source outputs a first current the DUT; measure a second set of voltages over time while the current source outputs a second current to the DUT, the second current having a different polarity to the first current; and measure a third set of voltages over time while the current source outputs a third current to the DUT, the third current having a same polarity as the first current. Furthermore, the test and measurement instrument includes one or more processors configured to derive a capacitance of the DUT based on the second and third currents.

### CROSS-REFERENCE TO RELATED APPLICATIONS

This application is a nonprovisional of and claims benefit of U.S. Provisional Application No. 63/562,841, titled “QUASISTATIC C-V METHOD WITH FIXED FORCE DC CURRENT AND LEAKAGE CORRECTION,” filed Mar. 8, 2024, and benefit of U.S. Provisional Application No. 63/700,105, titled “INTERFACE TRAP DENSITY OF A DEVICE USING FORCE CURRENT QUASISTATIC C-V,” filed Sep. 27, 2024. The disclosures of each of these applications are incorporated herein by reference in their entirety.

### TECHNICAL FIELD

This disclosure relates to test and measurement techniques, and more particularly to a test and measurement technique for power devices.

### BACKGROUND

Capacitance Voltage (C-V) measurements are used for analyzing semiconductor materials and in semiconductor device fabrication. C-V is particularly useful for characterizing Metal-Oxide Semiconductors (MOS). Some of the many MOS device properties extracted from C-V data include mobile charges in the oxide, oxide capacitance, interface traps, doping profile, flat band voltage, doping concentration, minority carrier lifetime, and input/output capacitances.

For most semiconductor C-V measurements, high frequency (typically 100 kHz to 1 MHz) is used. However, for some C-V measurements, a low frequency, or quasistatic, technique is required. This is the case for interface trap density (DIT) measurements on a MOScap, where quasistatic C-V is able to detect interface traps. At high frequency, interface traps cannot change state rapidly enough to contribute to the device capacitance. As a result, both the high and low frequency measurements are required to determine the number of trapped charges.

Available quasistatic C-V solutions usually involve forcing a voltage and measuring current using a Source Measure Unit (SMU). For example, the ramp rate technique and the very low frequency capacitance-voltage technique used by an SMU for C-V measurements uses current measurements to derive the capacitance of a device under test (DUT). These techniques can be effective on traditional silicon MOS devices. However, with high power devices, such as SiC MOS devices, the higher capacitance makes these techniques difficult to use because the higher capacitance can cause unstable results. The stability of a feedback ammeter of the SMU is often specified based on the load capacitance or the source impedance. Depending on the model of the SMU, the ammeter of the SMU may not be stable with even a few hundred picofarads of capacitance.

Accordingly, what is needed is a way to derive a quasistatic (DC) capacitance for high power devices using an SMU.

### DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a diagram showing a device under test (DUT) coupled to a source measure unit (SMU) for deriving the quasistatic capacitance-voltage (C-V) characteristics of the DUT, according to some examples

FIG. 2 includes graphs of the current vs time generated by a SMU and the voltage vs time across terminals of the SMU, according to some examples

FIG. 3 shows a leakage measurement circuit having a SMU and a circuit representing a DUT, according to some examples.

FIG. 4A is a graph illustrating voltage vs time of a DUT using the quasistatic capacitance-voltage technique described herein, according to some examples.

FIG. 4B is a graph illustrating the resulting forward and reverse C-V curves resulting from the quasistatic capacitance-voltage technique described herein, according to some examples.

FIG. 5 is a flowchart of the operations of the SMU to obtain the capacitance of a DUT, according to some examples.

FIG. 6 illustrates an SMU connected to silicon carbide (SiC) metal-oxide semiconductor (MOS) DUT showing the circuit potentials, according to some examples.

FIG. 7 is a graph of forward and reverse capacitance curves as a function of surface potential using a quasistatic capacitance-voltage technique, according to some examples.

FIG. 8 is a graph showing forward and reverse capacitance curves with the oxide capacitance removed as a function of surface potential based on the quasistatic capacitance-voltage technique, according to some examples.

FIG. 9 shows a plot of the interface trap density (DIT) as a function of surface potential (Vₛ) based on using a quasistatic capacitance-voltage technique, according to some examples.

FIG. 10 is a flowchart for deriving the interface trap capacitance using a quasistatic capacitance-voltage technique, according to some examples.

To facilitate understanding, identical reference numerals have been used, where possible, to designate identical elements that are common to the figures. It is contemplated that elements of one example may be beneficially incorporated in other examples.

### DESCRIPTION

The present disclosure describes deriving quasistatic capacitance using a source measure unit (SMU) by measuring voltage instead of current, because measuring voltage is stable with a capacitive load. This disclosure describes a Quasistatic Capacitance-Voltage (QSCV) measurement technique that uses a method of forcing a fixed current into the gate terminal of a device under test (DUT), such as a power device or a metal-oxide-semiconductor field-effect transistor (MOSFET), measuring the voltage as a function of time, and deriving capacitance therefrom. Some of the advantages to using the technique described herein on a power device include: requiring only one SMU with a preamp whereas other methods use two SMU; forcing current faster than forcing voltage methods; allowing for a steady state condition by forcing constant DC current to the DUT unlike stepping voltages; avoiding instability problems by measuring voltage when using an instrument in low output impedance mode to derive the capacitance; performing open correction; correcting for leakages; and working on larger capacitances greater than 20 pF.

The present disclosure involves forcing a positive current to preset and charge the DUT, reversing the current to negative, and reversing the current back to positive. After collecting the C-V data (measured Capacitance-Voltage vs time), the leakage current measurements are used to improve the charge calculation for leaky devices.

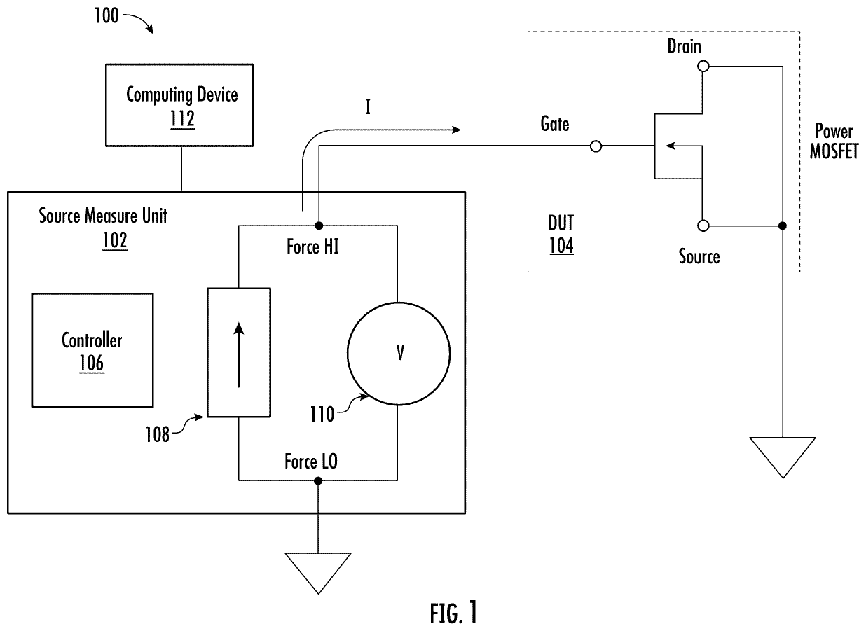

FIG. 1 is a diagram showing a circuit with a DUT coupled to a SMU for deriving the quasistatic C-V characteristics of the DUT, according to some examples. As shown in FIG. 1, the circuit 100 includes a SMU 102 coupled to a DUT 104. Specifically, the DUT 104 is a power MOSFET and has gate, drain, and source terminals as illustrated in FIG. 1. Accordingly, in the example shown in FIG. 1, the Force HI terminal of the SMU 102 is connected to the gate of the DUT 104 and the Force LO terminal of the SMU 102 is connected to the drain and source terminals of the DUT 104, which are shorted together. In some examples, a single SMU can derive the quasistatic C-V characteristics of a power MOSFET or capacitor. In examples described herein, the SMU can source and measures current and voltage.

As illustrated in FIG. 1, the SMU 102 includes a controller 106. The controller 106 of the SMU 102 includes firmware that controls the SMU 102. The SMU 102 includes a current source 108 and a voltmeter 110, and the controller 106 of the SMU 102 is configured to control the current source 108 and the voltmeter 110. In some examples, the controller 106 sends instructions to the current source 108 to generate a particular current to the DUT 104 and to the voltmeter 110 to measure the voltage across the Force HI terminal of the SMU 102 and the Force LO terminal of the SMU 102 at a particular time. The term “controller” as used herein refers to a programmable circuit. This discussion refers to the controller as a processor or a programmable circuit, which may include a general-purpose processor, digital signal processor, an Application Specific Integrated Circuit (ASIC), a field-programmable gate array (FPGA), or any other type of controller that can perform those functions.

In some examples, the circuit 100 includes a computing device 112 coupled to the SMU 102. In such examples, the SMU 102 provides the voltage measurements to the computing device 112, and the computing device 112 performs the quasistatic C-V calculations and determines the capacitance of the DUT 104. The computing device 112 transmits the capacitance of the DUT 104 to the SMU 102 so that the SMU 102 can compensate for leakage current of the DUT 104. In other examples, the SMU 102 performs the quasistatic C-V calculations and determines the capacitance of the DUT 104. The term “computing device” as used herein refers to a programmable circuit. This discussion refers to the computing device as a processor, a controller, or a programmable circuit, which may include a general-purpose processor, digital signal processor, an Application Specific Integrated Circuit (ASIC), a field-programmable gate array (FPGA), or any other type of controller that can perform those functions as described herein.

As described herein, the controller 106 of the SMU 102 derives the forward and reverse capacitance of the DUT 104 as a function of voltage as well as compensates for leakage current. To derive the capacitance, the SMU 102 is set to force current to the DUT 104 and measure voltage across the Force HI terminal of the SMU 102 and the Force LO terminal of the SMU 102 at a particular time. Forcing a constant current provides accurate control of the total charge (Q=I*dt) supplied to the device. Using constant current allows for a steady state condition for the instrument unlike voltage stepping, which can cause dynamic changes in the measurement equipment.

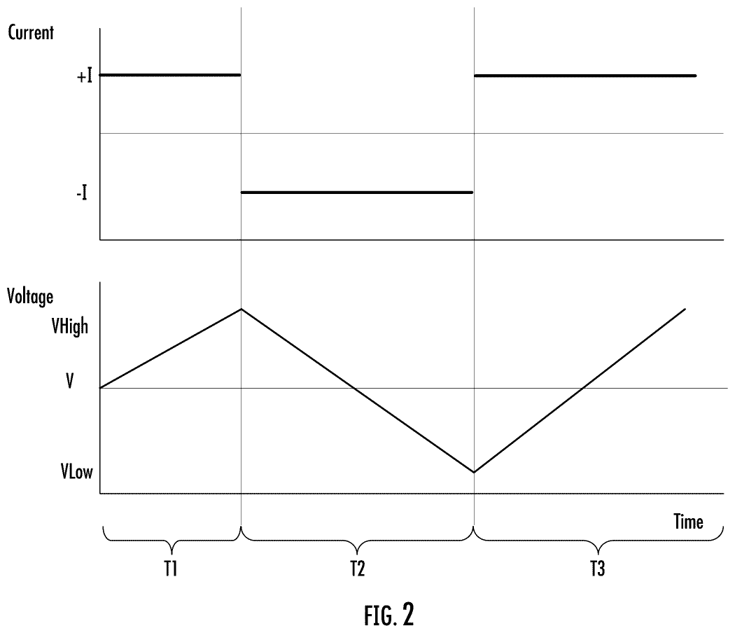

FIG. 2 includes graphs of the current vs time generated by the current source 108 of the SMU 102 and the voltage of the DUT 104 as measured by the voltmeter 110, as described herein. As illustrated, during time period T1, the SMU 102 forces a constant positive current (+I) using the current source 108 and measures the voltage (V) and time using the voltmeter 110 across the Force HI terminal of the SMU 102 and the Force LO terminal of the SMU 102 until the SMU 102 determines that the voltage as measured by the voltmeter 110 has reached a first predetermined voltage level VHigh. In some examples, the first predetermined voltage is a user-defined maximum voltage for the DUT 104. In some examples, the voltage measurements taken during time period T1 are not used for capacitance measurements.

After the SMU 102 determines that the voltage as read by the voltmeter 110 has reached the first predetermined voltage level, during time period T2, the SMU 102 changes the polarity of the current source 108 such that the current source 108 forces a constant negative current (−I) to the DUT 104. During time period T2, the SMU 102 measures the voltage across the Force HI terminal of the SMU 102 and the Force LO terminal of the SMU 102 using the voltmeter 110 until the SMU 102 determines that the voltage as measured by the voltmeter has reached a second predetermined voltage level (VLow). In some examples, the second predetermined voltage is a user-defined minimum voltage for the DUT 104. The voltage measurements during time period T2 may be referred to as a reverse sweep.

After the SMU 102 determines that the voltage as read by the voltmeter 110 has reached the first predetermined voltage level, during time period T3, the SMU 102 changes the polarity of the current source again such that the current source 108 forces a constant positive current (+I) to the DUT 104. During time period T3, the SMU 102 measures the voltage (V) across the Force HI terminal of the SMU 102 and the Force LO terminal of the SMU 102 using the voltmeter 110 until the SMU 102 determines that the voltage as measured by the voltmeter 110 has reached a third predetermined voltage level. In some examples, the predetermined voltage is a user-defined maximum voltage for the DUT 104. In further examples, the third predetermined voltage level can be the same as the first predetermined voltage level VHigh. The voltage measurements during time period T3 may be referred to as a forward sweep.

In some examples, the SMU 102 may use an arrangement of negative, positive, and negative currents instead of the arrangement of positive, negative, positive currents described above depending on the force current polarity.

Once the SMU 102 finishes with sending the different currents to the DUT 104 as described, the SMU 102 gathers the voltage measurements of the DUT 104 and generates capacitance vs voltage curves. Both the forward and reversed C-V curves can be extracted because the SMU 102 provided both the positive and negative current to the DUT 104 and measured the corresponding voltages for both positive and negative currents. The SMU 102 calculates the DUT capacitance (Cm) as follows:

$$I = {C}_{m} * \frac{dV}{dt}$$

$${C}_{m} = \frac{I}{\frac{dV}{dt}}$$

where I=forced current (A), V=measured voltage (V), t=measured time(s), Cm=derived capacitance (F).

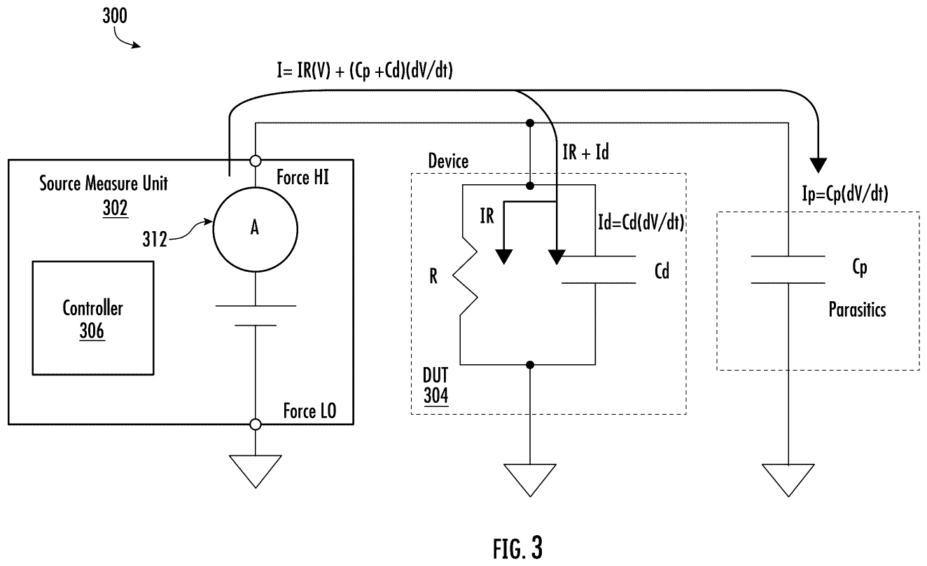

FIG. 3 shows a leakage measurement circuit having an R-C device representing a DUT and includes all the currents (in dotted lines) provided by a current source of the SMU, according to some examples herein. When making direct current (DC) measurements as described herein, such as for deriving quasistatic C-V, leakage resistances from the DUT 304 itself and parasitic capacitances in cabling can contribute significant errors if not corrected. The gate capacitance of the DUT 304, such as a power MOSFET or other capacitive devices, can be modelled as a parallel R-C circuit representing the DUT 304 as shown in FIG. 3. In this example, the resistor R represents the leakage resistance of the capacitor Cd. Additionally, the capacitor Cp represents the parasitic capacitances in cabling and/or in the circuit 300.

In some examples, the SMU 302 can include an ammeter 312 (controlled by a controller 306) used for measuring current and a voltage source (not illustrated in FIG. 3) for generating a voltage for the DUT 304. Accordingly, when measuring leakage current of a DUT 304, the SMU 302 forces voltage and measures current since the leakage current is a function of the applied voltage. As illustrated in FIG. 3, IR is the leakage current of the DUT 304; Id is the current due to the capacitance Cd of the DUT 304, which can be represented by Id=Cd(dV/dt); and Ip is the current due to the parasitic capacitance Cp in the system/circuit 300, which can be represented by Ip=Cp(dV/dt).

In the present disclosure, the SMU 302 can measure and compensate for the unwanted currents (IR and Ip) by performing an I-V sweep on the DUT 304 and subtracting the unwanted currents. The voltage sweep uses the actual measured voltage points from the constant forward and reverse current force test. From this test, the forced current is:

$$I = {I}_{R} ( V ) + \frac{( {C}_{p} + {C}_{d} ) dV}{dt}$$

The forced current can also be written as:

$$I = {C}_{m} \frac{dV}{dt}$$

$${C}_{m} = \frac{I}{\frac{dV}{dt}}$$

where Cm is the derived capacitance.

Accordingly, combining terms is as follows:

$${C}_{m} \frac{dV}{dt} = {I}_{R} + \frac{( {C}_{p} + {C}_{d} ) dV}{dt}$$

$${C}_{m} = \frac{IR}{\frac{dV}{dt}} + ( {C}_{p} + {C}_{d} )$$

$${C}_{m} = \frac{{I}_{R}}{I} {C}_{m} + ( {C}_{p} + {C}_{d} )$$

$${C}_{p} + {C}_{d} = {C}_{m} ( 1 - \frac{{I}_{R}}{I} )$$

where Cp=system parasitic capacitance, which includes cabling parasitic capacitance and probing parasitic capacitance. Therefore, measurement of the leakage (IR) allows to compensate for it, and calculate Cp+Cd from measured value Cm.

In probes up scenarios or other open circuit scenarios such that the DUT is not coupled to the circuit, there is no Cd, and what it measured is parasitic capacitance (Cp). Subtraction of this parasitic capacitance (Cd) from (Cp+Cd) provides extra level of accuracy and yields device capacitance compensated for the leakage and for parasitic capacitance.

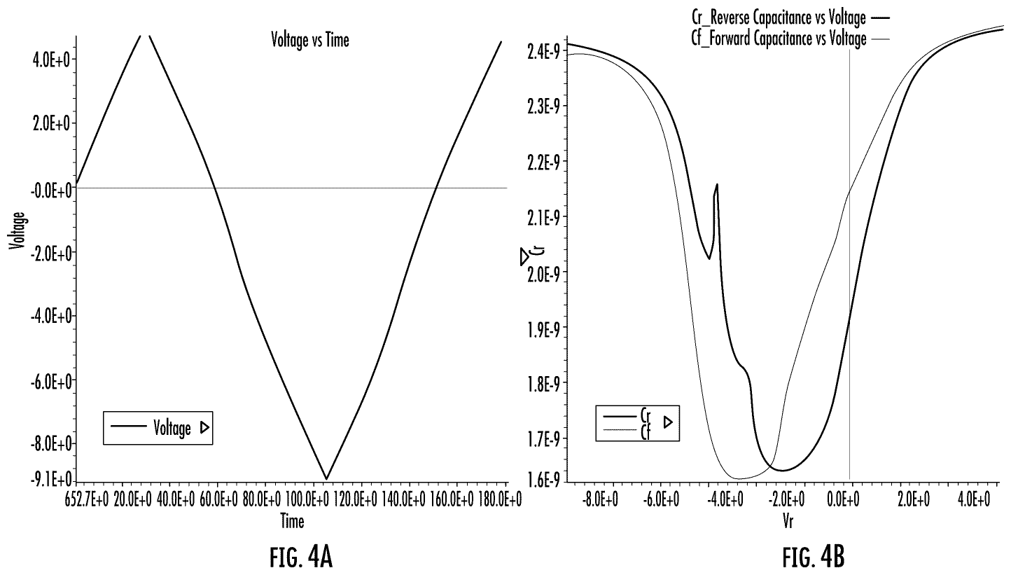

FIG. 4A is a graph illustrating the voltage vs time across the Force HI terminal of the SMU 102 and the Force LO terminal of the SMU 102, and FIG. 4B is a graph illustrating the resulting forward and reverse C-V curves corresponding to the voltage across the Force HI terminal of the SMU 102 and the Force LO terminal of the SMU 102 resulting from the quasistatic capacitance-voltage technique described herein. Specifically, the graph of FIG. 4B illustrates, the extracted QSCV forward and reverse capacitance vs voltage measurement results on a SiC power MOSFET. From these two curves, the SMU 302 may be able to extract other parameters, such as the trapped charges.

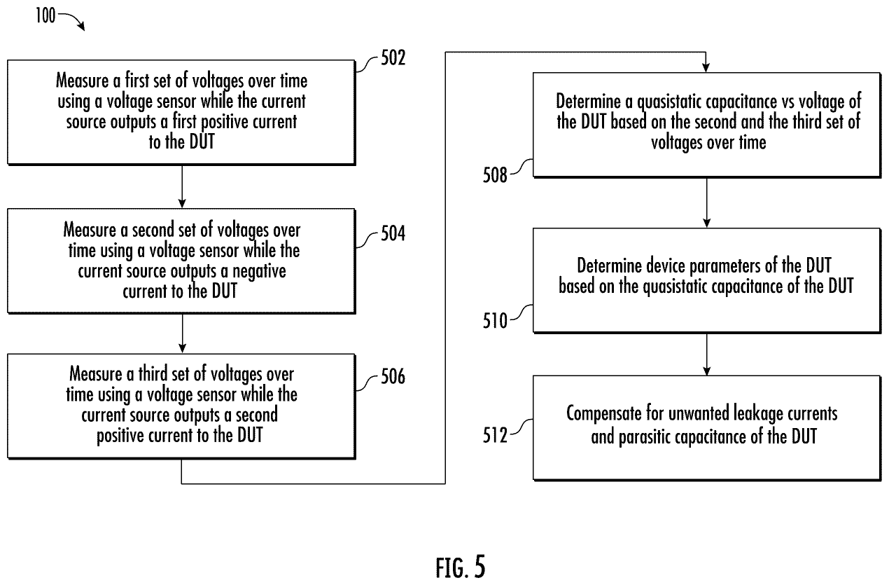

FIG. 5 is a flowchart of the operations of the SMU to obtain the capacitance of the DUT as described herein. Operations 500 is described with reference to the circuit 100 of FIG. 1 but may also be implemented with circuit 300 of FIG. 3. In some examples, the operations 500 may occur when the DUT 104 is coupled to the SMU 102.

Operations 500 begins with operation 502 of instructing the voltage sensor, such a voltmeter of FIG. 1, of the test and measurement instrument to measure a first set of voltages over time while the current source of the SMU outputs a first constant current to the DUT. In some examples, the current source of the SMU outputs the first constant current to the DUT until the voltage sensor of the SMU determines that the voltage across the Force HI terminal of the SMU 102 and the Force LO terminal of the SMU 102 has reached a first predetermined voltage threshold. In some examples, the first constant current to the DUT is a constant positive current, and by sending a constant positive current to the DUT, the SMU charges the DUT to the first predetermined voltage threshold. In further examples, the SMU tracks how long until the DUT reaches the first predetermined voltage threshold. The first predetermined voltage threshold can be a user-defined maximum voltage for the DUT. In other examples, the first constant current to the DUT is a constant negative current, and accordingly, the SMU tracks how long until the DUT reaches the first predetermined voltage threshold, which can be a user-defined minimum voltage for the DUT.

In some examples, the controller of the SMU sends instructions to the current source of the SMU to output the first positive current to the DUT.

Operations 500 then proceeds to operation 504 with instructing the voltage sensor to measure a second set of voltages over time using the voltage sensor, such a voltmeter 110 of FIG. 1, while the current source of the SMU outputs a second constant current to the DUT. The second constant current has a different polarity from the first constant current to the DUT. For example, if the first constant current was a positive constant current, then the second constant current is negative. Similarly, if the first constant current was a negative constant current, the second constant current is positive. In some examples, the current source of the SMU outputs the second constant current to the DUT until the voltage sensor of the SMU determines that the voltage across the Force HI terminal of the SMU 102 and the Force LO terminal of the SMU 102 has reached a second predetermined voltage threshold. In some examples, the second constant current to the DUT is a constant negative current, and by sending a negative current to the DUT, the SMU discharges the DUT and the voltage across the Force HI terminal of the SMU 102 and the Force LO terminal of the SMU 102 reflects such. In further examples, the SMU tracks how long until the DUT reaches the second predetermined voltage threshold. The second predetermined voltage threshold can be a user-defined minimum voltage for the DUT. In other examples, the second constant current to the DUT is a constant positive current, and accordingly, the SMU tracks how long until the DUT reaches the first predetermined voltage threshold, which can be a user-defined maximum voltage for the DUT.

Operations 500 then proceeds to operation 506 with instructing the voltage sensor to measure a third set of voltages over time while the current source of the SMU outputs a third constant current to the DUT. The third constant current has the same polarity from the first constant current to the DUT. For example, if the first constant current was a positive constant current, then the third constant current is also positive. Similarly, if the first constant current was a negative constant current, the third constant current is also negative. In some examples, the current source of the SMU outputs the third constant current to the DUT until the voltage sensor of the SMU determines that the voltage across the Force HI terminal of the SMU 102 and the Force LO terminal of the SMU 102 has reached a third predetermined voltage threshold. As mentioned, in some examples, the third constant current to the DUT is a constant positive current, and by sending a positive current to the DUT, the SMU charges the DUT and the voltage across the Force HI terminal of the SMU 102 and the Force LO terminal of the SMU 102 reflects such. In further examples, the SMU tracks how long until the DUT reaches the third predetermined voltage threshold. The third predetermined voltage threshold can be a user-defined maximum voltage, and in some examples, the third predetermined voltage threshold can be the same as the first predetermined voltage threshold. In other examples, the third constant current to the DUT is a constant negative current, and accordingly, the SMU tracks how long until the DUT reaches the third predetermined voltage threshold, which can be a user-defined minimum voltage for the DUT.

Operations 500 then proceeds to operation 508 with deriving the DUT capacitance based on the second and third constant currents and the second and third sets of voltages as a function of time. Operation 508 involves determining the quasistatic capacitance vs voltage of the DUT based on the second and third sets of voltages over time. In some examples, operations 508 involves gathering the voltage measurements gathered in operations 504, and 506 and calculating the DUT capacitance (Cm) as follows:

$$I = {C}_{m} * \frac{dV}{dt}$$

$${C}_{m} = \frac{I}{\frac{dV}{dt}}$$

where I=forced current (A), V=measured voltage (V), t=measured time(s), Cm=derived capacitance (F).

Operations 500 then proceeds to operation 510 with determining device parameters of the DUT based on the DUT quasistatic capacitance. With the DUT capacitance, the SMU can determine other parameters for the DUT, such as mobile charges in the oxide, oxide capacitance, or interface traps.

Operations 500 then proceeds to operation 512 with the SMU and the computing device compensating for unwanted leakage currents and parasitic capacitance of the DUT. As mentioned, the SMU can measure and compensate for the unwanted currents (IR and Ip) by performing an I-V sweep on the DUT and subtracting the unwanted currents. The voltage sweep uses the actual measured voltage points from the constant forward and reverse current force test and can thereby derive the capacitance, as described. Further, the SMU can determine system parasitic capacitance, which includes cabling parasitic capacitance and probing parasitic capacitance, and can compensate for the unwanted currents based on the previous calculations.

The quasistatic C-V technique herein has several advantages over other methods. Measuring voltage is faster than measuring low current and allows more data points to be collected with good accuracy. Feedback ammeters are often unstable with capacitive loads, and thus measuring voltage avoids noisy measurements. The technique described herein requires one SMU instead of two required by other methods. The technique herein incorporates leakage measurements and corrections that enable quasistatic techniques to be applied to leaky MOS devices. Quasistatic C-V measurements for both forward and reverse directions in one run allows charge trap characterization.

The present disclosure involves measuring voltage and not current which make the results faster, more accurate, and less noisy. The present disclosure involves only using one SMU instead of two. The present disclosure involves providing leakage correction at specific measured voltage points without using a differential method which can lead to noisy results.

This disclosure further describes a method to determine the interface trapped and other internal charges of a SiC MOS device using the Force Current QSCV measurement technique. Because SiC devices have significantly more internal charges than traditional Si devices, the measured capacitance needs to be plotted again the surface potential (Vₛ) as opposed to the gate voltage (V_{g}) for calculations of trapped charges. The interface trapped charge of a silicon MOS device is extracted from the capacitance difference of a low frequency (quasistatic) C-V_{g} curve and a high frequency (AC) curve. To observe internal charges of a SiC MOSFET, the forward and reverse quasistatic C-V sweeps can be used to extract this charge.

The technique for deriving this interface trap capacitance can be described in five steps: First, generate forward (Cf) and reverse (Cr) quasistatic capacitance versus gate voltage (V_{g}) curves on a SiC MOSFET using the force current quasistatic C-V technique described above. Second, derive surface potential (Vₛ) arrays for both forward and reverse sweeps. Third, interpolate the forward capacitance (CfDut) and reverse capacitance (CrDut) at each surface potential point. Fourth, subtract the oxide capacitance (Cₒₓ) from the forward (CfDut) and reverse (CrDut) measurements. Fifth, calculate the capacitance (CIT) and interface trap density (DIT) due to trapped charge from the difference of the forward and reverse curves as a function of the surface potential. These five steps are further explained herein.

While the present disclosure refers to a MOSFET, the present disclosure can potentially be applied to other devices. Further, while the present disclosure refers to interface charges, the present disclosure can potentially apply to other types of charges, including but not limited to oxide or mobile ion charges.

This disclosure works by generating forward and reverse C-V data using the forced current quasistatic method and then extracting the interface trap density as a function of surface potential.

As mentioned above, deriving the interface trap capacitance involves generating forward and reverse quasistatic C-V curves. Specifically, deriving this interface trap capacitance involves generating forward quasistatic capacitance (Cf) and reverse quasistatic capacitance (Cr) versus gate voltage (Vg) curves on a SiC MOSFET using the force current quasistatic C-V technique. The forced current QSCV technique uses a SMU to derive the quasistatic C-V of a DUT, such as a SiC MOSFET or MOScap. In this test, the SMU is forcing current and measuring voltage and time. The constant current provides accurate control of the total charge (Q=ΣI*dt) supplied to the DUT. As the constant current is forced to the DUT, both the forward and reverse C-V sweeps are derived from the forced current, voltage, and time. Capacitance (C) is calculated as follows:

$$I = C * \frac{dV}{dt}$$

$$C = \frac{I}{\frac{dV}{dt}}$$

where I is Forced Current (A), V is Measured Voltage (V), t is Measured Time(s), C is Derived Capacitance (F).

At this point in the test, voltage and time have been measured. The data needs to be spilt in the reverse and forward C-V sweeps to accurately represent the data. First in the reverse sweep, the reverse voltage (Vr), reverse sweep time (timeR) and reverse capacitance (Cr) are output. In the forward sweep, the reverse voltage (Vf), forward sweep time (timeF), and capacitance (Cf) are output.

It is observed from the forward and reverse C-V sweeps that there is both a shift in the voltage between the two curves as well as “peaks” and smaller curve features. Both the voltage shift and “peaks” are a result of internal devices charges, such as trapped charges, mobile ion charge, or charges related to the device structure. However, sometimes, during high frequency (AC) sweeps, the voltage shift and peaks are not observed.

As mentioned above, deriving this interface trap capacitance involves deriving surface potential (Vₛ) arrays for both forward and reverse sweeps. The capacitances of the forward and reverse voltage sweeps of a DUT are usually compared at the same gate voltage (V_{g}). Because SiC MOSFETs have significant internal charges, the forward and reverse QSCV curves as a function of the surface potential (Vₛ) are compared instead. Using Vₛ corrects for the “shifts” seen in the gate voltage between the forward and reverse curves and allows for the curves to be compared. Accurately measured charge allows for correction of the voltage drop across gate oxide to extract Vₛ.

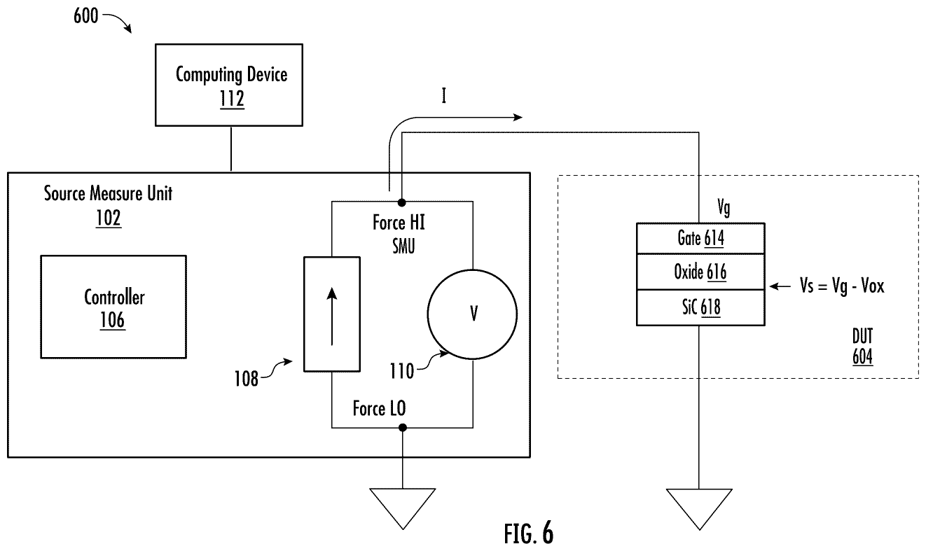

FIG. 6 illustrates a circuit with an SMU connected to SiC MOS DUT showing the circuit potentials. As illustrated in FIG. 6, the circuit 600 includes a SMU 102 coupled to a DUT 604 having a gate 614, an oxide 616, and SiC layer 618. The SMU 102 includes a current source 108 and a voltmeter 110. As illustrated in FIG. 6, the SMU 102 applies a constant current to the DUT 604 as well as the voltages, V_{g} and Vₛ. The voltage at the gate layer 614 of the DUT 604 is V_{g}. The voltage at the SiC/SiO₂ interface is the surface potential (Vₛ) and is represented by the equation:

$${V}_{s} = {V}_{g} - {V}_{ox}$$

Accordingly, to derive surface potential (Vₛ) arrays for both forward and reverse sweeps, the computing device 112 analyzes the reverse and forward capacitance arrays (Cr and Cf) to find the maximum value from either array. The maximum capacitance is defined as Cₒₓ, or oxide capacitance. Then, from each gate voltage V_{g}, the SMU 102 calculates the surface potential Vₛ using the oxide capacitance Cₒₓ and calculated charge (Q):

$${V}_{s} = {V}_{g} - \frac{Q}{{C}_{ox}}$$

The surface potential is spilt into two separate arrays for both sweeps. The output parameter, VₛR, represents the reverse sweep surface potential, and VₛF represents the forward sweep surface potential.

As mentioned above, deriving this interface trap capacitance involves interpolating the forward capacitance (CfDut) and reverse capacitance (CrDut) at each surface potential Vₛ point. Interpolating the forward capacitance (CfDut) and reverse capacitance (CrDut) at each surface potential Vₛ point involves comparing two data sets collected at different V_{g} but at the same surface potential Vₛ. To do this, the computing device 112 uses linear interpolation as follows: (1) determine the number of voltage step points but using the following equation

$$Δ V = \frac{Vmax - Vmin}{( points to plot ) - 1} ;$$

and (2) run the linear interpolation twice, once for the reverse sweep and another for the forward sweep to extract the interpolated capacitance points. The forward and reverse interpolated capacitance arrays are CrDut and CfDut.

As mentioned above, deriving this interface trap capacitance involves subtracting the Oxide Capacitance (Cₒₓ) from the Forward (CfDut) and Reverse (CrDut) Measurements. Specifically, the maximum capacitance (Cₒₓ) is subtracted from all CrDut and CfDut values. To do this, the SMU 102 uses linear interpolation on the reverse and forward voltage surface potential values, VₛR and VₛF. The computing device 112 calculates the forward and reverse interpolated capacitance arrays (CrDut and CfDut), and in each function, the computing device 112 removes the Cₒₓ value at each point, using the following two equations:

$$CfOnly = \frac{1}{\frac{1}{CfDut} - \frac{1}{Cox}}$$

$$CrOnly = \frac{1}{\frac{1}{CrDut} - \frac{1}{Cox}}$$

FIG. 7 is a graph of forward and reverse capacitance curves as a function of Vₛ. Specifically, FIG. 7 shows both the forward and reverse capacitance curves, CfDut and CrDut, plotted as a function of interface voltage instead of gate voltage.

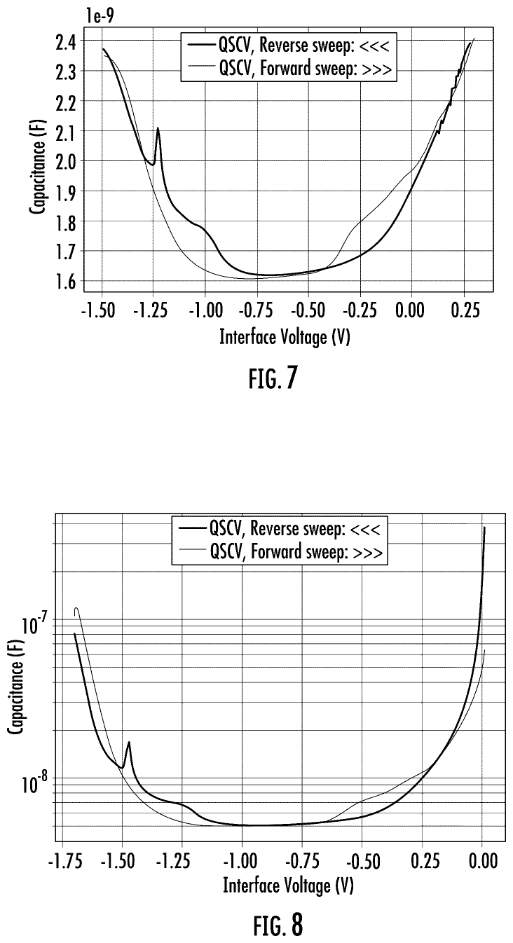

FIG. 8 is a graph showing Cf and Cr curves with Cₒₓ removed as a function of Vₛ. Specifically, with FIG. 8, with Cₒₓ removed, CrOnly and CfOnly are plotted as a function of interface voltage, now in a logarithmic scale.

As mentioned above, deriving the interface trap capacitance involves calculating the interface trapped capacitance (CIT) and density (DIT) due to trapped charge from the difference of the corrected forward and reverse curves as a function of the surface potential. In some examples, the computing device 112 uses the following equation to determine the interface trapped capacitance due to the trapped charge for the DUT 604:

$$CIT = \frac{{C}_{Fonly} ( {V}_{S} ) - {C}_{Ronly} ( {V}_{S} )}{gate area}$$

In some examples, the computing device uses the following equation to determine the interface trap density (DIT) due to the trapped charge for the DUT 604:

$$DIT = \frac{{C}_{Fonly} ( {V}_{S} ) - {C}_{Ronly} ( {V}_{S} )}{gate area * q}$$

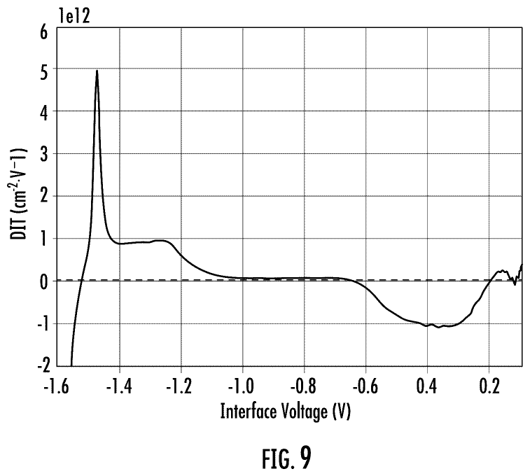

FIG. 9 shows a plot of the interface trap density (DIT) as a function of surface potential (Vₛ). Specifically, FIG. 9 shows the plotted difference between the interpolated forward and reverse capacitances versus interface voltage (Vₛ).

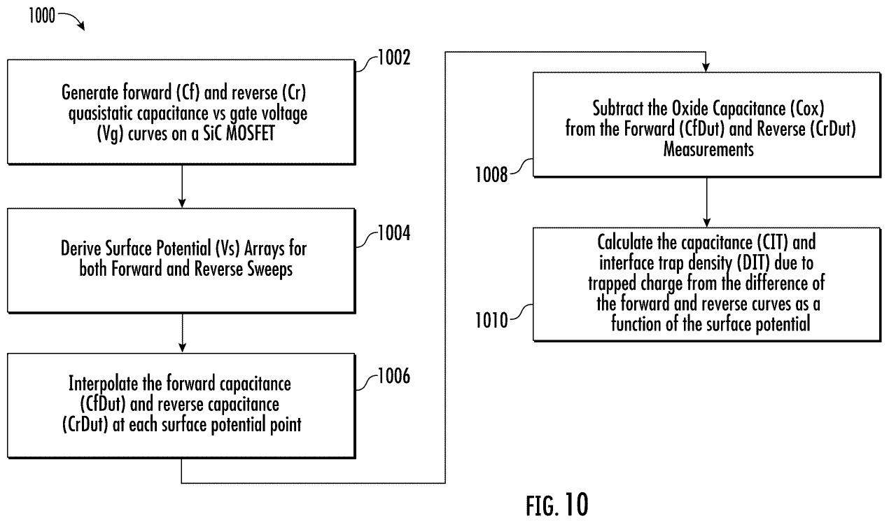

FIG. 10 is a flowchart of the operations of the SMU and computing device for deriving the interface trap capacitance using a quasistatic capacitance-voltage technique as described herein. Operations 1000 is described with reference to circuit 100 of FIG. 1 but may also be implemented with circuit 600 of FIG. 6.

Operations 1000 begins with operation 1002 in which the SMU generates the forward and reverse quasistatic capacitance vs gate voltage curves for a DUT. The DUT may be a SiC MOSFET. In some examples, operation 1002 includes some of the operations 500 of FIG. 5 in order to generate the forward and reverse quasistatic capacitance vs gate voltage curves of the DUT.

Operations 1000 then proceeds to operation 1004 in which the computing device derives surface potential arrays for forward sweep and reverse sweep. To derive surface potential (Vₛ) arrays for both forward and reverse sweeps, the SMU analyzes the reverse and forward capacitance arrays (Cr and Cf) to find the maximum value from either array. Then, from each gate voltage V_{g}, the computing device calculates the surface potential Vₛ using the oxide capacitance Cₒₓ and calculated charge (Q). The surface potential is spilt into two separate arrays for both sweeps. The output parameter VAR represents the reverse sweep surface potential, and VₛF represents the forward sweep surface potential.

Operations 1000 then proceeds to operation 1006 in which the computing device interpolates the forward capacitance and the reverse capacitance at each surface potential point of the surface potential arrays. In operation 1006, the computing device compares two data sets collected at different V_{g} but at the same surface potential Vₛ. To do this, the computing device uses linear interpolation as follows: (1) the computing device determines the number of voltage step points but using the following equation

$$Δ V = \frac{Vmax - Vmin}{( points to plot ) - 1} ;$$

and (2) the computing device runs the linear interpolation twice, once for the reverse sweep and another for the forward sweep to extract the interpolated capacitance points. The forward and reverse interpolated capacitance arrays are CrDut and CfDut.

Operations 1000 then proceeds to operation 1008 in which the computing device subtracts the oxide capacitance from the forward and reverse measurements. The computing device subtracts the maximum capacitance (Cₒₓ) from all CrDut and CfDut values by using linear interpolation on the reverse and forward voltage surface potential values, VₛR and VₛF. The computing device calculates the forward and reverse interpolated capacitance arrays (CrDut and CfDut), and in each function, the computing device removes the Cₒₓ value at each point, using the following two equations:

$$CfOnly = \frac{1}{\frac{1}{CfDut} - \frac{1}{Cox}}$$

$$CrOnly = \frac{1}{\frac{1}{CrDut} - \frac{1}{Cox}}$$

Operations 1000 then proceeds to operation 1010 in which the computing device calculates the interface trapped capacitance (CIT) and density (DIT) due to trapped charge from the difference of the corrected forward and reverse curves as a function of the surface potential. The computing device determines the interface trapped capacitance due to the trapped charge for the DUT using the gate area of the DUT, the C_{Fonly} points, and the C_{Ronly} points. Similarly, the computing device determines the interface trap density (DIT) due to the trapped charge for the DUT using the gate area of the DUT, the charge of the DUT, the C_{Fonly} points, and the C_{Ronly} points.

The present disclosure for calculating traps in SiC MOS devices from the forward and reverse sweeps offers advantages over other solutions. For example, quasistatic C-V measurements for both forward and reverse directions can be made in one run, which allows charge trap characterization. Another advantage is that the present disclosure allows for capacitance measurements as a function of interface potential and not just gate voltage. Yet another advantage is that the present disclosure involves extracting internal charges of the device, which are not detectable by the high frequency method. Furthermore, the present disclosure requires only one SMU instead of two required by other methods. Requiring only one SMU also avoids disruption of the measurement circuit when the two instruments need to be switched to the device.

In the present disclosure, the difference in the forward and reverse quasistatic (low frequency) capacitance versus voltage measurements is used to calculate the internal traps. Other techniques use the difference between high and low frequency C-V sweeps to derive the interface trap density.

Because charge is measured, the interface potential can be calculated, which enables the capacitance to be characterized as a function of the interface potential. In other techniques, the extraction of the interface potential is difficult because measurement of the oxide charge at a high frequency is difficult or impossible. Therefore, comparisons are usually made as a function of the gate voltage and not the interface potential. Using this technique, high frequency C-V measurements are not necessary.

In this disclosure, the singular forms “a,” “an,” and “the” include plural referents unless the context dictates otherwise. The term “or” is meant to be inclusive and means either, any, several, or all of the listed items. The terms “comprises,” “comprising,” “includes,” “including,” or other variations thereof, are intended to cover a non-exclusive inclusion such that a process, method, or product that comprises a list of elements does not necessarily include only those elements but may include other elements not expressly listed or inherent to such a process, method, article, or apparatus. Relative terms, such as “about,” “approximately,” “substantially,” and “generally,” are used to indicate a possible variation of ±10% of a stated or understood value.

The aspects of the present disclosure are susceptible to various modifications and alternative forms. Specific aspects have been shown by way of example in the drawings and are described in detail herein. However, one should note that the examples disclosed herein are presented for the purposes of clarity of discussion and are not intended to limit the scope of the general concepts disclosed to the specific aspects described herein unless expressly limited. As such, the present disclosure is intended to cover all modifications, equivalents, and alternatives of the described aspects in light of the attached drawings and claims.

References in the specification to aspect, example, etc., indicate that the described item may include a particular feature, structure, or characteristic. However, every disclosed aspect may or may not necessarily include that particular feature, structure, or characteristic. Moreover, such phrases are not necessarily referring to the same aspect unless specifically noted. Further, when the discussion described a particular feature, structure, or characteristic in connection with a particular aspect, such feature, structure, or characteristic can be employed in connection with another disclosed aspect whether or not such feature is explicitly described in conjunction with such other disclosed aspect.

Aspects of the disclosure may operate on a particularly created hardware, on firmware, digital signal processors, or on a specially programmed general-purpose computer including a processor operating according to programmed instructions. The terms controller or processor as used herein include microprocessors, microcomputers, Application Specific Integrated Circuits (ASICs), cloud-based servers, and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid-state memory, Random Access Memory (RAM), etc. As will be appreciated by one of skill in the art, the functionality of the program modules may be combined or distributed as desired in various aspects. In addition, the functionality may exist in whole or in part in firmware or hardware equivalents such as integrated circuits, field programmable gate arrays (FPGAs), and the like. Particular data structures may be used to implement more effectively one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that accessible by a computing device. By way of example, and not limitation, computer-readable media may comprise computer storage media and communication media.

Computer storage media means any medium that can store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can communicate computer-readable information. By way of example, and not limitation, communication media may include coaxial cables, fiber-optic cables, air, or any other media suitable for the communication of electrical, optical, Radio Frequency (RF), infrared, acoustic or other types of signals.

The disclosed aspects may be implemented, in some cases, in hardware, firmware, software, or any combination thereof. References made above to FPGAs and other integrated circuits such as voltage regulators, etc., may be replaced with any component that can perform the same functions. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

### Examples

Illustrative examples of the disclosed technologies are provided below. An embodiment of the technologies may include one or more, and any combination of, the examples described below.

Example 1 is a test and measurement instrument, including: a current source configured to output a constant current to a connected device under test (DUT); a voltage sensor configured to sense a voltage to the DUT, where the voltage sensor is configured to: measure a first set of voltages over time using the voltage sensor while the current source outputs a first constant current to the DUT; measure a second set of voltages over time using the voltage sensor while the current source outputs a second constant current to the DUT, the second constant current having a different polarity to the first constant current; and measure a third set of voltages over time using the voltage sensor while the current source outputs a third constant current to the DUT, the third constant current having a same polarity as the first constant current; and one or more processors configured to execute code that causes the one or more processors to derive a capacitance of the DUT based on the first, second, and third constant currents and the first, second, and third sets of voltages as a function of time.

Example 2 is the test and measurement instrument of Example 1, where the DUT is a power device or a metal-oxide-semiconductor device.

Example 3 is the test and measurement instrument of Example 1 or Example 2, where the voltage sensor is configured to measure the second voltage while the current source outputs the second constant current to the DUT after the first voltage reaches a predetermined threshold.

Example 4 is the test and measurement instrument of any one of Example 1-3, where the voltage sensor is configured to measure the third voltage while the current source outputs the third constant current to the DUT after the second set of voltages reaches a predetermined threshold.

Example 5 is the test and measurement instrument of any one of Example 1-4, where the voltage sensor is configured to measure the first set of voltages until the first set of voltages reaches a predetermined threshold.

Example 6 is the test and measurement instrument of any one of Example 1-5, where the one or more processors are further configured to determine device parameters of the DUT based on the capacitance of the DUT.

Example 7 is the test and measurement instrument of any one of Example 1-6, where the capacitance is a quasistatic capacitance of the DUT.

Example 8 is the test and measurement instrument of any one of Example 1-7, where the one or more processors are further configured to compensate for one or more unwanted currents based on the leakage current of the DUT and the capacitance of the test fixturing and cabling.

Example 9 is the test and measurement instrument of any one of Example 1-8 where the one or more processors configured to derive the capacitance of the DUT involves using the following equation: C_m=I/(dV/dt).

Example 10 is a method for a test and measurement instrument, including: instructing a voltage sensor of the test and measurement instrument to measure a first set of voltages over time measurements while a current source of the test and measurement instrument outputs a first constant current to a device under test (DUT) coupled to the test and measurement instrument; instructing the voltage sensor of the test and measurement instrument to measure a second set of voltages over time measurements while the current source outputs a second constant current to the DUT, the second constant current having a different polarity from the first constant current; instructing the voltage sensor of the test and measurement instrument to measure a third set of voltages over time measurements while the current source outputs a third constant current to the DUT, the third constant current having a same polarity as the first constant current; and deriving a quasistatic capacitance of the DUT based on the second and third constant currents and the second and third sets of voltages as a function of time.

Example 11 is the method of Example 10, where the DUT is a power device or a metal-oxide semiconductor device.

Example 12 is T the method of Example 10 or Example 11, where deriving the capacitance of the DUT involves using the following equation: C_m=I/(dV/dt).

Example 13 is the method of any one of Example 10-12, where instructing a voltage sensor of the test and measurement instrument to measure the second set of voltages over time may include instructing a voltage sensor of the test and measurement instrument to measure the second set of voltages over time while the current source outputs the second constant current to the DUT after the first set of voltages reaches a user defined threshold.

Example 14 is the method of any one of Example 10-13, where instructing a voltage sensor of the test and measurement instrument to measure the third set of voltages over time may include instructing a voltage sensor of the test and measurement instrument to measure the third set of voltages over time while the current source outputs the third constant current to the DUT after the second set of voltages reaches a second defined threshold.

Example 15 is the method of any one of Example 10-14, where instructing a voltage sensor of the test and measurement instrument to measure may include instructing a voltage sensor of the test and measurement instrument to measure the first set of voltages over time until the first set of voltages reaches a user defined threshold.

Example 16 is the method of any one of Example 10-15, further including determining device parameters of the DUT based on the capacitance of the DUT.

Example 17 is the method of any one of Example 10-16, where the capacitance of the DUT is a quasistatic capacitance of the DUT.

Example 18 is the method of any one of Example 10-17, further including: compensating for unwanted leakage currents of the DUT and the capacitance of the test fixturing and cabling.

Example 19 is a test and measurement system, including: a test and measurement instrument including: a current source configured to output a constant current to a connected device under test (DUT); a voltage sensor configured to sense a voltage to the DUT; and one or more processors configured to execute code that causes the one or more processors to: instruct the voltage sensor to measure a first set of voltages over time while the current source outputs a first constant current to the DUT; instruct the voltage sensor to measure a second set of voltages over time while the current source outputs a second constant current to the DUT, the second constant current having a different polarity to the first constant current; instruct the voltage sensor to measure a third set of voltages over time while the current source outputs a third constant current to the DUT, the third constant current having a same polarity as the first constant current; and derive a quasistatic capacitance of the DUT based on the second and third constant currents and the second and third sets of voltages as a function of time.

Example 20 is the test and measurement system of Example 19, where the one or more processors configured to derive the capacitance of the DUT involves using the following equation: C_m=I/(dV/dt).

Example 21 is a method for driving interface trap capacitance with a test and measurement instrument, including: generating a forward quasistatic capacitance sweep and a reverse quasistatic capacitance sweep using a current source and a voltage sensor of the test and measurement instrument configured to sense a voltage through a connected device under test (DUT); deriving arrays of surface potential voltages for the forward quasistatic capacitance sweep and the reverse quasistatic capacitance sweep; interpolating forward capacitance of the DUT and reverse capacitance at each surface potential voltage based on the arrays of surface potential voltages for the forward quasistatic capacitance sweep and the reverse quasistatic capacitance sweep; subtracting the oxide capacitance from each of the interpolated forward capacitances and each of the interpolated reverse capacitances to generate forward-only quasistatic capacitance sweep and a reverse-only quasistatic capacitance sweep; and calculating the capacitance and interface trap density of the DUT from a difference of the forward-only quasistatic capacitance sweep and reverse-only quasistatic capacitance sweep as a function of the surface potential voltages.

Example 22 is the method of Example 21, where generating the forward quasistatic capacitance sweep and the reverse quasistatic capacitance sweep may include deriving a first array of voltage and time measurements using the voltage sensor while a current source outputs a first constant current to the DUT; deriving a second array of voltage and time measurements using the voltage sensor while the current source outputs a second constant current to the DUT; deriving the third array of voltage and time measurements using the voltage sensor while the current source outputs a third constant current to the DUT; and determining the forward quasistatic capacitance sweep and the reverse quasistatic capacitance sweep based on the second and third arrays of voltage and time measurements and the second and third constant currents.

Example 23 is the method of Example 21 or Example 22, where the DUT is a power device or a metal-oxide semiconductor device.

Example 24 is the method of any one of Example 21-23, where deriving arrays of surface potential voltages may include: determining an oxide capacitance for the forward quasistatic capacitance sweep and the reverse quasistatic capacitance sweep; and calculating the arrays of surface potential voltages based on a total charge and the oxide capacitance.

Example 25 is the method of any one of Example 21-24, where deriving the array of surface potential voltages involves the following equation: V_s=V_g−Q/C_ox.

Example 26 is the method of any one of Example 21-25, where interpolating forward capacitance of the DUT and reverse capacitance at each surface potential voltage may include: determining a number of voltage steps; and performing linear interpolation for the forward quasistatic capacitance sweep and for the reverse quasistatic capacitance sweep to extract interpolated capacitance points.

Example 27 is the method of any one of Example 21-26, where subtracting the oxide capacitance involves the following equations: CfOnly=1/(1/CfDut−1/Cox), and CrOnly=1/(1/CrDut−1/Cox).

Example 28 is the method of any one of Example 21-27, where calculating the capacitance and interface trap density of the DUT may include: calculating the capacitance due to trapped charges based on the gate area.

Example 29 is the method of any one of Example 21-28, where calculating the capacitance and interface trap density of the DUT may include calculating the interface trap density based on the gate area and the total charge.

Example 30 is a test and measurement system, including: a current source configured to output a current; a voltage sensor configured to sense a voltage through a connected device under test (DUT); and one or more processors configured to execute code that causes the one or more processors to: generate a forward quasistatic capacitance sweep and a reverse quasistatic capacitance sweep using the current source and the voltage sensor; derive arrays of surface potential voltages for the forward quasistatic capacitance sweep and the reverse quasistatic capacitance sweep; interpolate forward capacitance of the DUT and reverse capacitance at each surface potential voltage based on the arrays of surface potential voltages for the forward quasistatic capacitance sweep and the reverse quasistatic capacitance sweep; subtract the oxide capacitance from each of the interpolated forward capacitances and each of the interpolated reverse capacitances; and calculate the capacitance and interface trap density of the DUT from a difference of the forward quasistatic capacitance sweep and reverse quasistatic capacitance sweep as a function of the surface potential voltages

Example 31 is the test and measurement system of Example 30, where the current source is a direct current source.

Example 32 is the test and measurement system of Example 30 or Example 31, where the DUT is a power device or a metal-oxide-semiconductor device.

Example 33 is the test and measurement instrument of any one of Example 30-32, where the one or more processors configured to derive arrays of surface potential voltages is further configured to: determine an oxide capacitance for the forward quasistatic capacitance sweep and the reverse quasistatic capacitance sweep; and calculate the arrays of surface potential voltages based on a total charge and the oxide capacitance.

Example 34 is the test and measurement system of any one of Example 30-33, where the one or more processors configured to interpolate forward capacitance of the DUT and reverse capacitance at each surface potential voltage is further configured to: determine a number of voltage steps; and perform linear interpolation for the forward quasistatic capacitance sweep and for the reverse quasistatic capacitance sweep to extract interpolated capacitance points.

Example 35 is the test and measurement system of any one of Example 30-34, where the one or more processors configured to calculate the capacitance and interface trap density of the DUT is further configured to calculate the capacitance due to trapped charges based on the gate area.

Example 36 is the test and measurement system of any one of Example 30-35, where the one or more processors configured to calculate the capacitance and interface trap density of the DUT is further configured to calculate the interface trap density based on the gate area and the total charge.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

What is claimed:

1. A test and measurement instrument, comprising:
a current source configured to output a constant current to a connected device under test (DUT);
a voltage sensor configured to sense a voltage to the DUT, wherein the voltage sensor is configured to:
measure a first set of voltages over time using the voltage sensor while the current source outputs a first constant current the DUT;
measure a second set of voltages over time using the voltage sensor while the current source outputs a second constant current to the DUT, the second constant current having a different polarity to the first constant current; and
measure a third set of voltages over time using the voltage sensor while the current source outputs a third constant current to the DUT, the third constant current having a same polarity as the first constant current; and
one or more processors configured to execute code that causes the one or more processors to derive a capacitance of the DUT based on the first, second, and third constant currents and the first, second, and third sets of voltages as a function of time.

2. The test and measurement instrument of claim 1, wherein the DUT is a power device or a metal-oxide-semiconductor device.

3. The test and measurement instrument of claim 1, wherein the voltage sensor is configured to measure the second voltage while the current source outputs the second constant current to the DUT after the first voltage reaches a predetermined threshold.

4. The test and measurement instrument of claim 1, wherein the voltage sensor is configured to measure the third set of voltages while the current source outputs the third constant current to the DUT after the second voltage reaches a predetermined threshold.

5. The test and measurement instrument of claim 1, wherein the voltage sensor is configured to measure the first set of voltages until the first set of voltages reaches a predetermined threshold.

6. The test and measurement instrument of claim 1, wherein the one or more processors are further configured to determine device parameters of the DUT based on the capacitance of the DUT.

7. The test and measurement instrument of claim 1, wherein the capacitance is a quasistatic capacitance of the DUT.

8. The test and measurement instrument of claim 1, wherein the one or more processors are further configured to compensate for one or more unwanted currents based on the leakage current of the DUT and the capacitance of the test fixturing and cabling.

9. The test and measurement instrument of claim 1 wherein the one or more processors configured to derive the capacitance of the DUT involves using the following equation:
$${C}_{m} = \frac{I}{\frac{dV}{dt}} .$$

10. A method for a test and measurement instrument, comprising:
instructing a voltage sensor of the test and measurement instrument to measure a first set of voltages over time measurements while a current source of the test and measurement instrument outputs a first constant current to a device under test (DUT) coupled to the test and measurement instrument;
instructing the voltage sensor of the test and measurement instrument to measure a second set of voltages over time measurements while the current source outputs a second constant current to the DUT, the second constant current having a different polarity from the first constant current;
instructing the voltage sensor of the test and measurement instrument to measure a third set of voltages over time measurements while the current source outputs a third constant current to the DUT, the third constant current having a same polarity as the first constant current; and
deriving a quasistatic capacitance of the DUT based on the second and third constant currents and the second and third sets of voltages as a function of time.

11. The method of claim 10, wherein the DUT is a power device or a metal-oxide semiconductor device.

12. The method of claim 10, wherein instructing a voltage sensor of the test and measurement instrument to measure the second set of voltages over time comprises instructing a voltage sensor of the test and measurement instrument to measure the second set of voltages over time while the current source outputs the second constant current to the DUT after the first voltage reaches a user defined threshold.

13. The method of claim 10, wherein instructing a voltage sensor of the test and measurement instrument to measure the third set of voltages over time comprises instructing a voltage sensor of the test and measurement instrument to measure the third set of voltages over time while the current source outputs the third constant current to the DUT after the second set of voltages reaches a second defined threshold.

14. The method of claim 10, wherein instructing a voltage sensor of the test and measurement instrument to measure comprises instructing a voltage sensor of the test and measurement instrument to measure the first set of voltages over time until the first voltage reaches a user defined threshold.

15. The method of claim 10, further comprising determining device parameters of the DUT based on the capacitance of the DUT.

16. The method of claim 10, wherein the capacitance of the DUT is a quasistatic capacitance of the DUT.

17. The method of claim 10, further comprising: compensating for unwanted leakage currents of the DUT and the capacitance of the test fixturing and cabling.

18. The method of claim 11, wherein deriving the capacitance of the DUT involves using the following equation:
$${C}_{m} = \frac{I}{\frac{dV}{dt}} .$$

19. A test and measurement system, comprising:
a test and measurement instrument comprising:
a current source configured to output a constant current to a connected device under test (DUT);
a voltage sensor configured to sense a voltage to the DUT; and
one or more processors configured to execute code that causes the one or more processors to:
instruct the voltage sensor to measure a first set of voltages over time while the current source outputs a first constant current to the DUT;
instruct the voltage sensor to measure a second set of voltages over time while the current source outputs a second constant current to the DUT, the second constant current having a different polarity to the first constant current;
instruct the voltage sensor to measure a third set of voltages over time while the current source outputs a third constant current to the DUT, the third constant current having a same polarity as the first constant current; and
derive a quasistatic capacitance of the DUT based on the second and third constant currents and the second and third sets of voltages as a function of time.

20. The test and measurement system of claim 19, wherein the one or more processors configured to derive the capacitance of the DUT involves using the following equation:
$${C}_{m} = \frac{I}{\frac{dV}{dt}} .$$
